(19) United States
(12) Patent Application Publication
(10) Pub. No.: US 2026/0113010 A1
(43) Pub. Date: Apr. 23, 2026

(54) POWER AMPLIFIER

(71) Applicant: Sumitomo Electric Industries, Ltd., Osaka (JP)

(72) Inventor: Hirotaka ASAMI, Osaka (JP)

(73) Assignee: Sumitomo Electric Industries, Ltd., Osaka (JP)

(21) Appl. No.: 19/358,497

(22) Filed: Oct. 15, 2025

(30) Foreign Application Priority Data
Oct. 17, 2024 (JP) 2024-181835

(51) Int. Cl. H03F 3/60; H01P 5/18; H03F 1/56; H03F 3/24

(52) U.S. Cl. CPC H03F 3/602; H01P 5/18; H03F 1/56; H03F 3/245; H03F 2200/198

(57) ABSTRACT

A power amplifier includes a balanced type amplifier and a control amplifier. The balanced type amplifier includes a first amplifier and a second amplifier and is configured to amplify an input power. The control amplifier is configured to form a load modulated balanced amplifier together with the balanced type amplifier and output a control signal including a fundamental wave component or a harmonic component of the input power to each of the first amplifier and the second amplifier. The control amplifier is disposed between the first amplifier and the second amplifier.

### CROSS REFERENCE TO RELATED APPLICATIONS

This application claims priority based on Japanese Patent Application No. 2024-181835 filed on Oct. 17, 2024, and the entire contents of the Japanese patent application are incorporated herein by reference.

### TECHNICAL FIELD

The present disclosure relates to a power amplifier.

### BACKGROUND

A power amplifier that performs load modulation is disclosed in each of U.S. Patent Application Publication No. 2018/0205348 specification (Patent literature 1), Japanese National Patent Publication No. 2022-506367 (Patent literature 2), and U.S. Patent Application Publication No. 2022/0255506 specification (Patent literature 3). Such a power amplifier is also referred to as a load modulated balanced amplifier (LMBA).

Patent literature 1: U.S. Patent Application Publication No. 2018/0205348 specification

Patent literature 2: Japanese National Patent Publication No. 2022-506367

Patent literature 3: U.S. Patent Application Publication No. 2022/0255506 specification

Non-patent literature 1: Jingzhou Pang, Yue Li, Meng Li, Yikang Zhang, Xin Yu Zhou, Zhijiang Dai and Anding Zhu, Analysis and Design of Highly Efficient Wideband RF-Input Sequential Load Modulated Balanced Power Amplifier, IEEE Transactions on Microwave Theory and Techniques, Vol. 68, No. 5, May 2020.

### SUMMARY

A power amplifier according to the present disclosure includes a balanced type amplifier and a control amplifier. The balanced type amplifier includes a first amplifier and a second amplifier and is configured to amplify an input power. The control amplifier is configured to form a load modulated balanced amplifier (LMBA) together with the balanced type amplifier and output a control signal including a fundamental wave component or a harmonic component of the input power to each of the first amplifier and the second amplifier. The control amplifier is disposed between the first amplifier and the second amplifier.

### BRIEF DESCRIPTION OF THE DRAWINGS

FIG. 1 is a circuit block diagram showing an application example of a power amplifier according to an embodiment 1.

FIG. 2 is a circuit block diagram showing a configuration of a power amplifier according to a comparative example.

FIG. 3 is a diagram showing a configuration of a combiner in a comparative example.

FIG. 4 is a circuit block diagram showing a basic configuration of a power amplifier according to the embodiment 1.

FIG. 5 is a diagram showing a first example of a configuration of a coupler in the embodiment 1.

FIG. 6 is a diagram showing a second example of a configuration of a coupler in the embodiment 1.

FIG. 7 is a layout diagram showing an example of an arrangement of components of a power amplifier according to a comparative example.

FIG. 8 is a layout diagram showing an example of an arrangement of components of a power amplifier according to the embodiment 1.

FIG. 9 is a circuit block diagram showing a first example of a configuration of a power amplifier according to an example 1 of the embodiment 1.

FIG. 10 is a diagram for describing a first condition for input power to a rat-race coupler.

FIG. 11 is a diagram for describing a case where a phase control circuit is not provided.

FIG. 12 is a diagram for describing a second condition regarding a phase relationship between power and a control signal.

FIG. 13 is a diagram for describing a second example of an arrangement of a phase control circuit.

FIG. 14 is a diagram for describing a third example of an arrangement of a phase control circuit.

FIG. 15 is a diagram showing examples of Smith chart of simulation results regarding impedance matching of the power amplifier according to the example 1 of the embodiment 1.

FIG. 16 is a diagram showing an example of a simulation result regarding power efficiency of the power amplifier according to the example 1 of the embodiment 1.

FIG. 17 is a circuit block diagram showing an example of a configuration of a power amplifier according to an example 1 of an embodiment 2.

FIG. 18 is a diagram showing an example of a configuration of a branch line coupler.

FIG. 19 is a circuit block diagram showing an example of a configuration of a power amplifier according to an example 2 of the embodiment 2.

FIG. 20 is a diagram for describing a configuration of a distributed coupling coupler.

### DETAILED DESCRIPTION

A power amplifier (load modulated balanced amplifier) disclosed in Patent literature 1, Patent literature 2, Patent literature 3, or the like includes a balanced type amplifier (BA) and a control amplifier. The present inventor has focused on the fact that, in such a power amplifier, a balanced type amplifier may oscillate depending on an embodiment. It is desirable to suppress oscillation in the power amplifier.

One of the objectives of the present disclosure is to suppress oscillation in a power amplifier.

Description of Embodiments of Present Disclosure First, embodiments of the present disclosure will be listed and described.

(1) A power amplifier according to the present disclosure includes a balanced type amplifier including a first amplifier and a second amplifier and configured to amplify an input power, and a control amplifier configured to form a load modulated balanced amplifier together with the balanced type amplifier and output a control signal including a fundamental wave component or a harmonic component of the input power to each of the first amplifier and the second amplifier. The control amplifier is disposed between the first amplifier and the second amplifier.

According to the configuration in the above (1), the control amplifier is disposed between the first amplifier and the second amplifier. Thus, a distance between the first amplifier and the second amplifier is maintained, and the control amplifier serves as a shield between the first amplifier and the second amplifier. Thus, positive feedback caused by a part of power output from one of the first amplifier and the second amplifier returning to the other becomes less likely to occur (details will be described later). As a result, oscillation in the power amplifier can be suppressed.

(2) In the above (1), the balanced type amplifier may include a directional coupler having a plurality of ports and a phase difference of 180 degrees.

The plurality of ports may include a first port configured to receive a power amplified by the first amplifier, a second port configured to receive a power amplified by the second amplifier, a third port configured to receive the control signal, and a fourth port coupled to a load. The third port may be disposed between the first port and the second port along an outer periphery of the directional coupler having a phase difference of 180 degrees.

According to the configuration in the above (2), by using the directional coupler having a phase difference of 180 degrees, the control amplifier can be disposed between the first amplifier and the second amplifier without crossing of wirings.

(3) In the above (2), the directional coupler having a phase difference of 180 degrees may be a rat-race coupler having a distribution line. The first port, the third port, the second port, and the fourth port may be arranged in this order along the distribution line. The power amplifier may further include one or more phase control circuits configured to control a phase of the power amplified by the second amplifier with respect to a phase of the power amplified by the first amplifier.

According to the configuration in the above (3), by appropriately controlling the phase by the phase control circuit, it is possible to efficiently supply power to the load while suppressing unnecessary power supply to the control amplifier.

(4) In the above (3), the rat-race coupler may be a ring loose coupled rat-race coupler in which the distribution line has a ring shape.

According to the configuration in the above (4), cost of the power amplifier can be reduced by using the ring loose coupled rat-race coupler.

(5) In the above (3), the rat-race coupler may be a coupled-line rat-race coupler having two coupled lines between the first port and the fourth port, and the two coupled lines are arranged to be coupled to each other.

According to the configuration in the above (5), cost of the power amplifier can be reduced by using the coupled-line rat-race coupler. In addition, a high-bandwidth and small-sized power amplifier can be realized.

(6) In the above (1), the balanced type amplifier may include a directional coupler having a plurality of ports and a phase difference of 90 degrees. The plurality of ports may include a first port configured to receive a power amplified by the first amplifier, a second port configured to receive a power amplified by the second amplifier, a third port configured to receive the control signal, and a fourth port coupled to a load.

According to the configuration in the above (6), even when the directional coupler having a phase difference of 90 degrees is used, the control amplifier can be disposed between the first amplifier and the second amplifier.

(7) In the above (6), the directional coupler having a phase difference of 90 degrees may be a branch line coupler having a distribution line. The first port, the second port, the fourth port, and the third port may be arranged in this order along the distribution line. The first port may be coupled to the first amplifier by a first transmission line.

The second port may be coupled to the second amplifier by a second transmission line. The third port may be coupled to the control amplifier by a third transmission line. The first transmission line, the second transmission line, and the third transmission line may be mounted at a multilayer substrate including a plurality of conductor layers. The first transmission line and the third transmission line may be mounted on different conductor layers among the plurality of conductor layers and may three-dimensionally intersect each other such that the control amplifier is disposed between the first amplifier and the second amplifier.

According to the configuration in the above (7), by making the first transmission line and the third transmission line to three-dimensionally intersect, the control amplifier can be disposed between the first amplifier and the second amplifier using the directional coupler having a phase difference of 90 degrees.

(8) In the above (6), the directional coupler having a phase difference of 90 degrees may be a distributed coupling coupler. The first port, the fourth port, the second port, and the third port may be arranged in this order along an outer periphery of the distributed coupling coupler. The distributed coupling coupler may have a multilayer structure including a first conductive layer and a second conductive layer. The first port and the third port may be coupled to each other by a first wiring disposed in the first conductive layer. The second port and the fourth port may be coupled to each other by a second wiring disposed in the second conductive layer. The first wiring and the second wiring may be arranged so as to at least partially overlap each other when the distributed coupling coupler is viewed in a plan view.

According to the configuration in the above (8), by arranging the first wiring and the second wiring so as to partially overlap each other inside the distributed coupling coupler, the control amplifier can be disposed between the first amplifier and the second amplifier using the directional coupler having a phase difference of 90 degrees.

(9) In the above (1) to (8), the power amplifier may further include a divider configured to divide the input power for the first amplifier, the second amplifier, and the control amplifier.

According to the configuration in the above (9), by using the divider, it is possible to easily realize a circuit configuration that distributes the input power to the first amplifier, the second amplifier, and the control amplifier.

(10) In the above (9), the divider may include a first Wilkinson divider and a second Wilkinson divider. The first Wilkinson divider may be configured to divide the input power for the first amplifier and the second Wilkinson divider. The second Wilkinson divider may be configured to further divide the input power divided by the first Wilkinson divider, for the second amplifier and the control amplifier.

According to the configuration in the above (10), by using the Wilkinson divider as the divider, isolation and impedance matching among the first amplifier, the second amplifier, and the control amplifier can be easily realized.

### Details of Embodiments of Present Disclosure

Next, embodiments of the present disclosure will be described in detail with reference to the drawings. In the drawings, the same or corresponding parts are denoted by the same reference numerals, and description thereof will not be repeated. At least some of the embodiments described below may be freely combined.

### Description of Terms

In the present disclosure and the embodiments thereof, the term “high frequency” means electromagnetic waves in MHz band or GHz band (frequency band of 1 MHz or more and less than 1 THz). The high frequency includes microwave. The term “microwave” means electromagnetic waves in a band 300 MHz or more and less than 300 GHz.

### Embodiment 1

### Overall Configuration

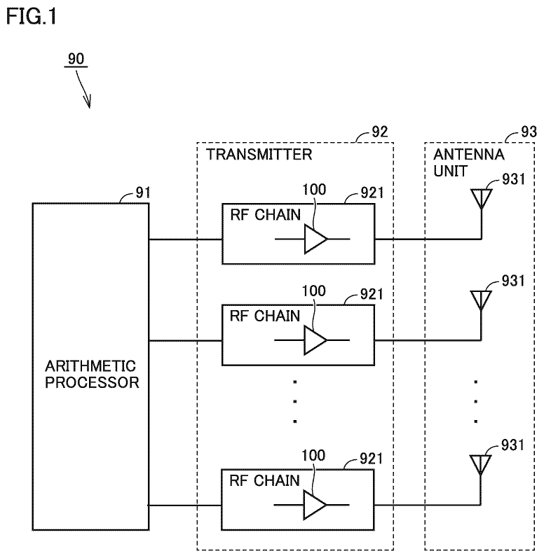

FIG. 1 is a circuit block diagram showing an application example of a power amplifier according to an embodiment 1. A power amplifier 100 is applied to a base station in this example. A base station 90 is, for example, a massive multiple input multiple output (Massive MIMO) base station used in fifth generation mobile communication system (5G). The base station 90 includes an arithmetic processor 91, a transmitter 92, and an antenna unit 93.

The arithmetic processor 91 performs digital signal processing (baseband processing or the like) for information transmitted from the base station 90 at the time of communication between the base station 90 and a communication device (not shown).

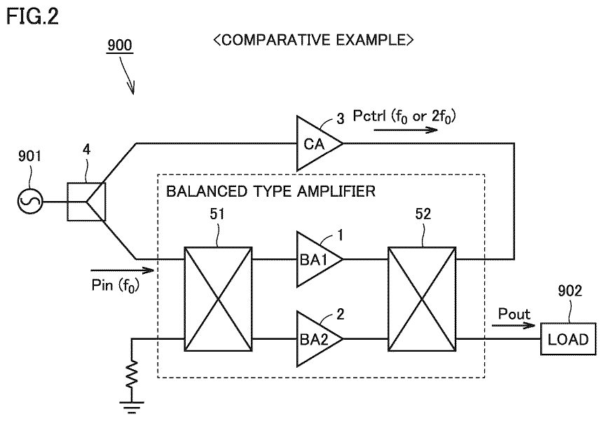

The transmitter 92 includes a plurality of radio frequency (RF) chains 921. Each of the plurality of RF chains 921 includes the power amplifier 100 in addition to a filter, a switch, a mixer, a D/A converter, and the like (none of which is shown). A configuration of the power amplifier 100 will be described in detail with reference to FIG. 2 and subsequent drawings.

The antenna unit 93 includes a plurality of antennas 931. The plurality of antennas 931 are connected to the plurality of RF chains 921, respectively.

The base station 90 is merely an example of an application of the power amplifier 100, and the application of the “power amplifier” according to the present disclosure is not limited thereto. The “power amplifier” according to the present disclosure may be applied to various devices (portable terminal or the like) used in a mobile communication system, for example.

### Configuration of Power Amplifier

### Comparative Example

In order to facilitate understanding of the power amplifier 100 according to the embodiment 1, first, a configuration of a power amplifier according to a comparative example will be briefly described.

FIG. 2 is a circuit block diagram showing a configuration of the power amplifier according to the comparative example. A power amplifier 900 is a load modulated balanced amplifier (LMBA). The power amplifier 900 includes a first amplifier 1, a second amplifier 2, a control amplifier (CA) 3, a divider 4, a distributor 51, and a combiner 52.

The divider 4 divides an input power Pin from an alternating current power supply 901 into two. The input power Pin is a high frequency (typically microwaves) in a frequency f₀. A part of the input power Pin is supplied to the distributor 51. The distributor 51 distributes the input power Pin to the first amplifier 1 and the second amplifier 2. Each of the first amplifier 1 and the second amplifier 2 amplifies the input power Pin distributed thereto and outputs the amplified power to the combiner 52. The combiner 52 combines the power amplified by the first amplifier 1 and the power amplified by the second amplifier 2, and supplies a combined power to a load 902. In the comparative example, the first amplifier 1 and the second amplifier 2 form a balanced type amplifier together with the distributor 51 and the combiner 52.

The other part of the input power Pin divided by the divider 4 is supplied to the control amplifier 3. The control amplifier 3 generates a control signal Pctrl from the input power Pin.

The control signal Pctrl includes a fundamental wave component (component of frequency f₀) or harmonic components (components of frequency 2f₀ or higher) of the input power Pin to the balanced type amplifier. The control amplifier 3 load-modulates the balanced type amplifier by supplying the fundamental wave component of the control signal Pctrl to the combiner 52. The control amplifier 3 may inject the harmonic components of the control signal Pctrl into the combiner 52. This is referred to as “harmonic injection”. The power efficiency of the balanced type amplifier can be improved by the harmonic injection.

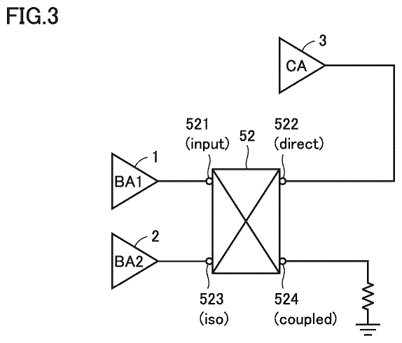

FIG. 3 is a diagram showing a configuration of the combiner 52 in the comparative example. The combiner 52 is a directional coupler having a phase difference of 90 degrees, and more specifically, a 90 degrees hybrid coupler. The combiner 52 is a branch line coupler in this example.

The combiner 52 includes an input port 521, an isolation port (also referred to as a blocking port) 523, and two output ports. Hereinafter, the two output ports are referred to as a direct port (also referred to as through port) 522 and a coupled port 524. These four ports are arranged in the order of the input port 521, the direct port 522, the coupled port 524, and the isolation port 523 clockwise along an outer periphery of the branch line coupler. Although not shown, a configuration of the distributor 51 is equivalent to the configuration of the combiner 52.

### Present Embodiment

Next, a configuration of the power amplifier 100 according to the embodiment 1 will be described in detail.

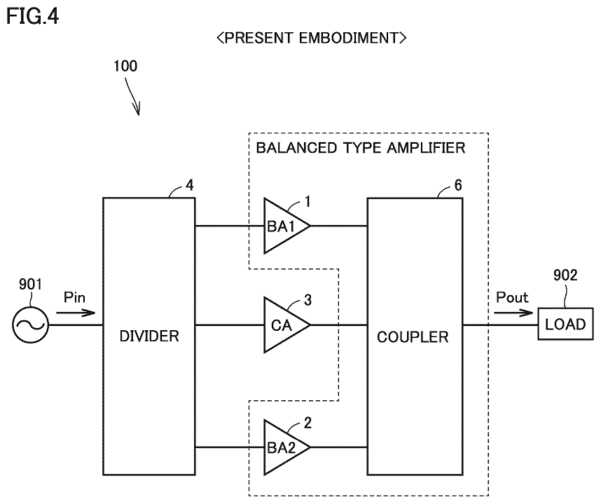

FIG. 4 is a circuit block diagram showing a basic configuration of the power amplifier according to the embodiment 1. The power amplifier 100 is an LMBA similarly to the power amplifier 900 according to the comparative example. The power amplifier 100 includes the first amplifier 1, the second amplifier 2, the control amplifier 3, the divider 4, and a coupler 6.

The divider 4 divides the input power Pin having a frequency of f₀ from the alternating current power supply 901 into three in this example. The input power Pin is distributed to the first amplifier 1, the second amplifier 2, and the control amplifier 3. By using the divider 4, a circuit configuration for distributing the input power Pin to the first amplifier 1, the second amplifier 2, and the control amplifier 3 can be easily realized. Each of the first amplifier 1 and the second amplifier 2 amplifies the input power Pin distributed thereto from the divider 4, and outputs the amplified power to the coupler 6.

The first amplifier 1 and the second amplifier 2 have approximately the same size (layout area). The first amplifier 1 and the second amplifier 2 are implemented by, for example, gallium nitride (GaN) high electron mobility transistors (HEMTs). However, the implementation of each amplifier is not limited to this. The first amplifier 1 and the second amplifier 2 may be implemented by an insulated gate bipolar transistor (IGBT) or a metal-oxide-semiconductor field-effect transistor (MOSFET) (for example, a laterally diffused MOSFET (LDMOSFET)). The material of each of the first amplifier 1 and the second amplifier 2 may be silicon (Si), silicon carbide (SiC), or the like.

The control amplifier 3 generates the control signal Pctrl by amplifying the frequency f₀ and outputs the control signal Pctrl to the coupler 6. The control signal Pctrl may include a harmonic component equal to or more than the frequency 2f₀, as described in this example. The control amplifier 3 is implemented by, for example, a GaN HEMT, similarly to the first amplifier 1 and the second amplifier 2. The control amplifier 3 may be implemented by an IGBT of Si or SiC, or may be implemented by a MOSFET of Si or SiC.

The first amplifier 1 and the second amplifier 2 form a balanced type amplifier together with the coupler 6. The balanced type amplifier performs load modulation by the fundamental wave component of the control signal Pctrl from the control amplifier 3. In addition, the balanced type amplifier may perform harmonic injection by a harmonic component of the control signal Pctrl. The balanced type amplifier generates an output power Pout from the input power Pin by load modulation or harmonic injection. The balanced type amplifier supplies the output power Pout to the load 902.

Note that in this example, the input power Pin from the alternating current power supply 901 is distributed to all three amplifiers. However, the power amplifier 100 may be configured to distribute the input power Pin to the first amplifier 1 and the second amplifier 2, and to supply power (not shown) different from the input power Pin to the control amplifier 3.

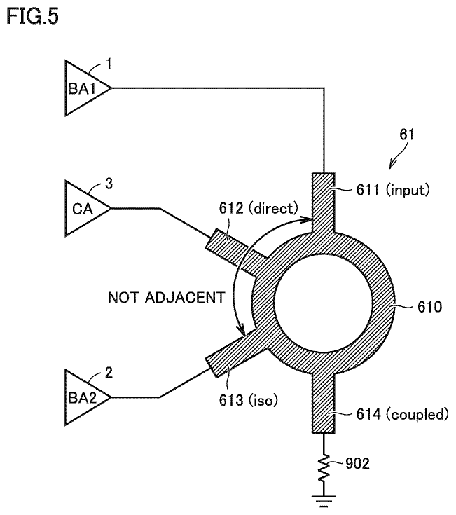

FIG. 5 is a diagram showing a first example of a configuration of the coupler 6 in the embodiment 1. The coupler 6 in the embodiment 1 is a directional coupler having a phase difference of 180 degrees, and more specifically, a 180 degrees hybrid coupler. The coupler 6 is a rat-race coupler in this example.

A rat-race coupler 61 includes a ring-shaped distribution line 610, an input port 611, a direct port 612, an isolation port 613, and a coupled port 614. These ports are arranged in this order counterclockwise along the distribution line 610. These ports may be arranged in the same order clockwise along the distribution line 610.

The input port 611 is coupled to an output node of the first amplifier 1. The isolation port 613 is coupled to an output node of the second amplifier 2. The direct port 612 is coupled to an output node of the control amplifier 3. The coupled port 614 is coupled to the load 902.

Note that the input port 611 corresponds to the “first port” according to the present disclosure. The direct port 612 corresponds to the “third port” according to the present disclosure. The isolation port 613 corresponds to the “second port” according to the present disclosure. The coupled port 614 corresponds to the “fourth port” according to the present disclosure.

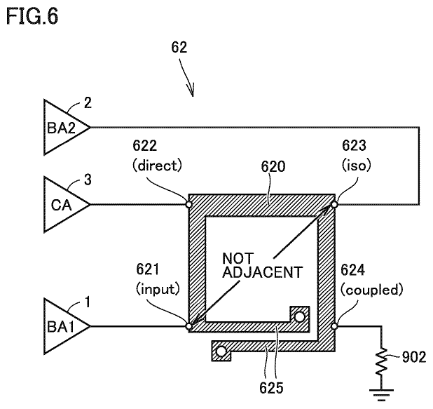

FIG. 6 is a diagram showing a second example of a configuration of the coupler 6 in the embodiment 1. The coupler 6 may be a different type of rat-race coupler than the rat-race coupler 61 shown in FIG. 5. A rat-race coupler 62 shown in FIG. 6 differs from the rat-race coupler 61 in that the rat-race coupler 62 further includes two coupled lines 625 between an input port 621 and a coupled port 624 that are disposed at a narrow interval so as to be electromagnetically coupled to each other. The other configuration of the rat-race coupler 62 is similar to the configuration of the rat-race coupler 61, and thus the description thereof will not be repeated.

The rat-race coupler 61 may be referred to as a ring loose coupled rat-race coupler. The rat-race coupler 62 may be referred to as a coupled-line rat-race coupler. By using the ring loose coupled rat-race coupler, cost of the power amplifier 100 can be reduced. By using the coupled-line rat-race coupler, cost of the power amplifier 100 can be reduced, and in addition, the power amplifier 100 having high-bandwidth can be realized with small size.

### Comparison of Arrangement

In general, a part of power (signal) output from an output node of an amplifier returns to an input node of the amplifier (in other words, positive feedback is applied), and thus oscillation of the amplifier may occur. The oscillation of the amplifier may be affected by the arrangement of the components.

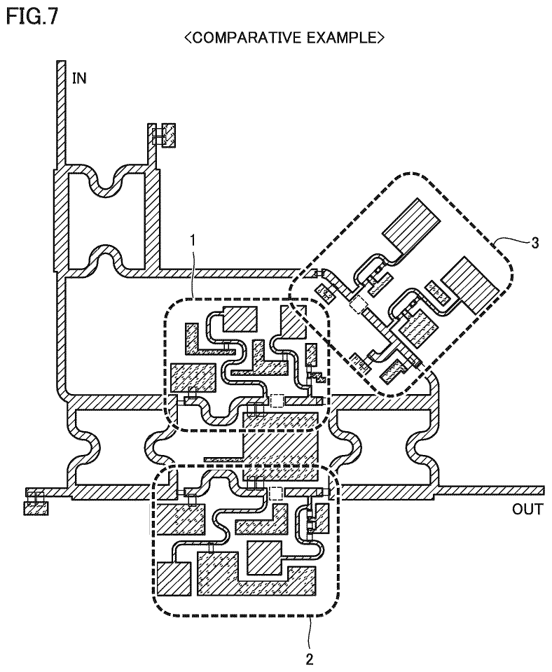

FIG. 7 is a layout diagram showing an example of an arrangement of components of the power amplifier 900 according to a comparative example. In the comparative example, a part of power output from the output node of the first amplifier 1 returns to the input node of the first amplifier 1. In addition, in the comparative example, as shown in FIG. 7, the first amplifier 1 and the second amplifier 2 are arranged adjacent to each other. In such an arrangement, a distance between the first amplifier 1 and the second amplifier 2 is short. Thus, the part of the power output from the output node of the first amplifier 1 may also return to the input node of the second amplifier 2. Similarly, a part of power output from the output node of the second amplifier 2 may return to the input node of the first amplifier 1 in addition to returning to the input node of the second amplifier 2.

In this manner, in the comparative example, not only the positive feedback of the first amplifier 1 itself and the positive feedback of the second amplifier 2 itself, but also the positive feedback from one of the first amplifier 1 and the second amplifier 2 to the other may occur.

Thus, depending on conditions such as the bandwidth of the input power, the power amplifier 900 may have a possibility to oscillate.

The arrangement in which the first amplifier 1 and the second amplifier 2 are adjacent to each other is considered to be derived from a port arrangement of the branch line coupler used as the combiner 52 in the comparative example. More specifically, as shown in FIG. 3, the input port 521 and the isolation port 523 are arranged successively along the outer periphery of the branch line coupler.

When the output node of the first amplifier 1 is coupled to the input port 521 and the output node of the second amplifier 2 is coupled to the isolation port 523, the first amplifier 1 and the second amplifier 2 are naturally adjacent to each other.

In contrast, in the embodiment 1, the rat-race coupler 61 is adopted instead of a branch line coupler. In the rat-race coupler 61, as shown in FIG. 5, the input port 611 and the isolation port 613 are arranged discontinuously, and the direct port 612 is disposed between the input port 611 and the isolation port 613. The direct port 612 is coupled to the output node of the control amplifier 3. Thus, as shown in FIGS. 4 and 5, the first amplifier 1 and the second amplifier 2 are disposed so as to sandwich the control amplifier 3 therebetween. In other words, in the embodiment 1, the control amplifier 3 is disposed between the first amplifier 1 and the second amplifier 2. The rat-race coupler 62 shown in FIG. 6 is also similar.

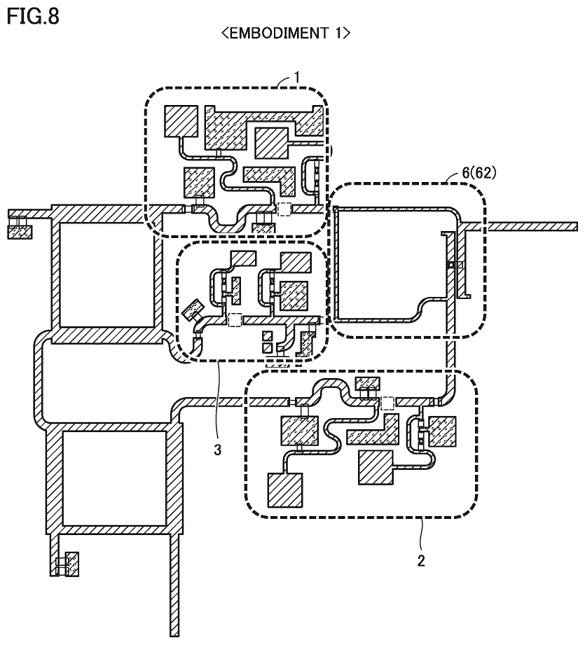

FIG. 8 is a layout diagram showing an example of an arrangement of components of the power amplifier 100 according to the embodiment 1. In the arrangement of the embodiment 1 shown in FIG. 8, the first amplifier 1 and the second amplifier 2 are separated from each other and the first amplifier 1 and the second amplifier 2 are shielded by the control amplifier 3, as compared with the arrangement of the comparative example shown in FIG. 7. Thus, positive feedback from one of the first amplifier 1 and the second amplifier 2 to the other becomes less likely to occur. Thus, according to the embodiment 1, oscillation in the power amplifier 100 can be suppressed.

### Example 1 of Embodiment 1

### Circuit Configuration

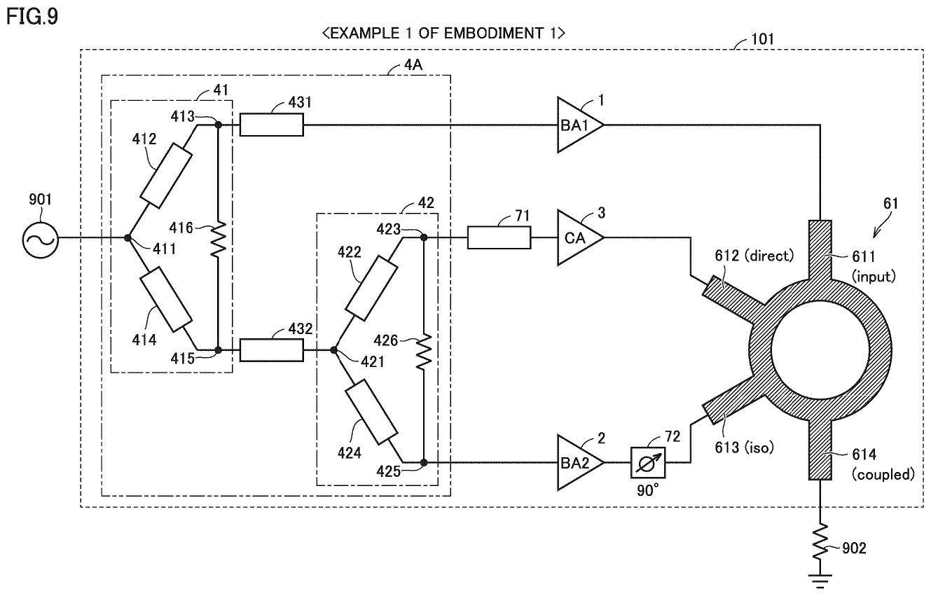

FIG. 9 is a circuit block diagram showing a first example of a configuration of a power amplifier according to an example 1 of the embodiment 1. A power amplifier 101 includes the first amplifier 1, the second amplifier 2, the control amplifier 3, a divider 4A, the rat-race coupler 61, a phase shifter 71, and a phase control circuit 72. The divider 4A includes a first Wilkinson divider 41, a second Wilkinson divider 42, a transmission line 431, and a transmission line 432. The power amplifier 101 may include the rat-race coupler 62 (see FIG. 6) instead of the rat-race coupler 61.

The first Wilkinson divider 41 includes a branching portion 411, a transmission line 412, an output port 413, a transmission line 414, an output port 415, and an isolation portion 416.

The branching portion 411 branches a transmission line from an input port coupled to the alternating current power supply 901 into a transmission line to the transmission line 412 and a transmission line to the transmission line 414. The transmission line 412 is a λ/4 (λ is a wavelength) transmission line that couples the branching portion 411 and the output port 413. The transmission line 414 is a λ/4 transmission line that couples the branching portion 411 and the output port 415. The isolation portion 416 matches impedance between the output port 413 and the output port 415 and insulates the output port 413 and the output port 415 from each other.

The second Wilkinson divider 42 includes a branching portion 421, a transmission line 422, an output port 423, a transmission line 424, an output port 425, and an isolation portion 426.

The branching portion 421 branches a transmission line from the transmission line 432 into a transmission line to the transmission line 422 and a transmission line to the transmission line 424. The transmission line 422 is a λ/4 transmission line that couples the branching portion 421 and the output port 423. The transmission line 424 is a λ/4 transmission line that couples the branching portion 421 and the output port 425. The isolation portion 426 matches impedance between the output port 423 and the output port 425 and insulates the output port 423 and the output port 425 from each other.

In this manner, isolation and impedance matching between the first amplifier 1, the second amplifier 2, and the control amplifier 3 can be easily realized by using the first Wilkinson divider 41 and the second Wilkinson divider 42 as dividers. Further, the phase difference between power output from the first amplifier 1 and power output from the second amplifier 2 can be set to a desired value (90 degrees in the example described later).

The phase shifter 71 is coupled between the output port 423 of the second Wilkinson divider 42 and an input node of the control amplifier 3. The phase shifter 71 delays the phase of the signal supplied from the second Wilkinson divider 42 to the control amplifier 3. In the present example, the phase delay amount by the phase shifter 71 may be adjusted so that the phase of the power supplied from the first amplifier 1 to the input port 611 of the rat-race coupler 61 and the phase of the control signal Pctrl supplied from the control amplifier 3 to the direct port 612 of the rat-race coupler 61 become appropriate phases.

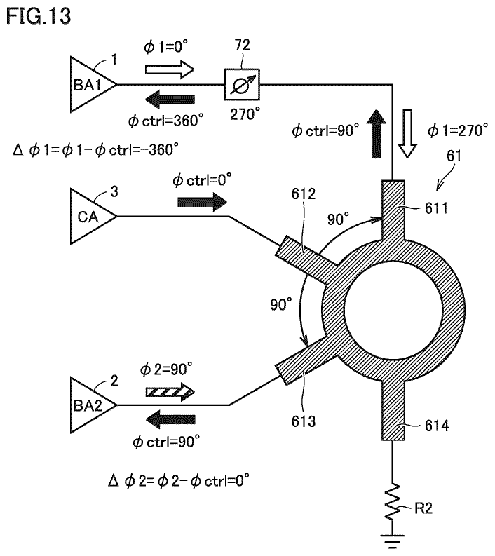

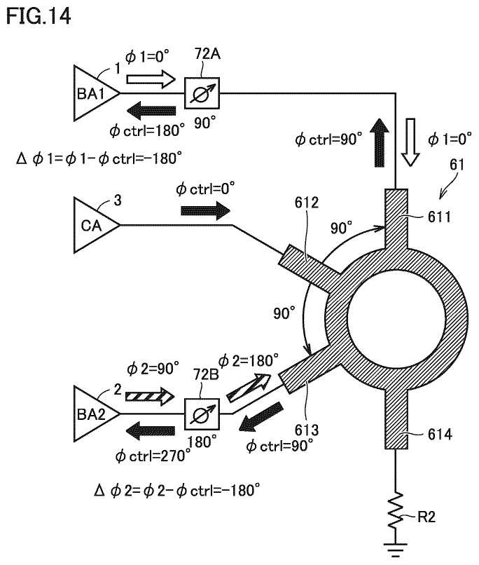

The phase control circuit 72 is coupled between the output node of the second amplifier 2 and the isolation port 613 of the rat-race coupler 61 in the present example. However, as described later, the phase control circuit 72 may be coupled between the output node of the first amplifier 1 and the input port 611 of the rat-race coupler 61 (see FIG. 13). The phase control circuits 72 may be coupled between the output node of the first amplifier 1 and the input port 611, and coupled between the output node of the second amplifier 2 and the isolation port 613 (see FIG. 14).

The phase control circuit 72 is configured to control a phase difference between power amplified by the first amplifier 1 and power amplified by the second amplifier 2, and to control a phase difference between the power amplified by the first amplifier 1 and/or the power amplified by the second amplifier 2 and the control signal Pctrl from the control amplifier 3. In this example, the phase control circuit 72 is configured to delay the phase of the power amplified by the second amplifier 2 by 90 degrees and delay the phase of the control signal Pctrl transmitted from the control amplifier 3 to the second amplifier 2 by 90 degrees.

It is desirable that the phase delay amounts by the phase shifter 71 and the phase control circuit 72 are determined so as to satisfy the following two conditions.

### First Condition of Phase Control

The term “first condition” means a phase condition regarding input power to the rat-race coupler 61. More specifically, the first condition is a condition for efficiently combining the input power from the first amplifier 1 to the input port 611 of the rat-race coupler 61 and the input power from the second amplifier 2 to the isolation port 613 of the rat-race coupler 61.

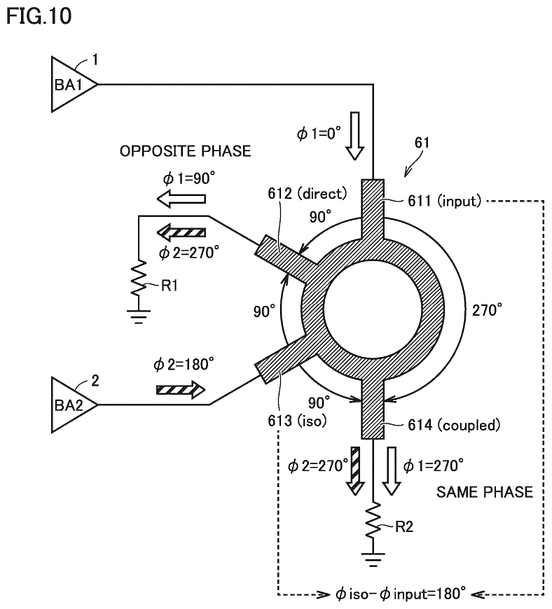

FIG. 10 is a diagram for describing a first condition for input power to the rat-race coupler 61. For simplicity, the phase control circuit 72 is not provided. It is also assumed that a resistor R1 is coupled to the direct port 612 of the rat-race coupler 61 instead of the control amplifier 3, and a resistor R2 is coupled to the coupled port 614 of the rat-race coupler 61 instead of the load 902.

The phase difference between the input port 611 and the direct port 612, the phase difference between the direct port 612 and the isolation port 613, and the phase difference between the isolation port 613 and the coupled port 614 are all 90 degrees. The phase difference between the input port 611 and the coupled port 614 is 270 degrees.

The phase of the power (indicated by a white arrow) transmitted from the first amplifier 1 to the input port 611 is denoted by φ1. The phase of the power (indicated by an arrow with diagonal hatching) transmitted from the second amplifier 2 to the isolation port 613 is denoted by φ2. These two powers have the same amplitude.

The first condition is a condition that the phase φ1 at the input port 611 and the phase φ2 at the isolation port 613 are in the opposite phase. In this example, it is assumed that the phase φ1 is equal to 0 degrees and the phase φ2 is equal to 180 degrees.

First, power supplied from the input port 611 or the isolation port 613 to the rat-race coupler 61 and output from the direct port 612 will be described. As the power having the phase φ1 at the input port 611 which is equal to 0 degrees is transmitted to the direct port 612, a phase delay of 90 degrees is added to the power, and thus the phase φ1 at the direct port 612 is 90 degrees. As the power having the phase φ2 at the isolation port 613 which is equal to 180 degrees is transmitted to the direct port 612, a phase delay of 90 degrees is added to the power, and thus the phase φ2 at the direct port 612 is 270 degrees. Thus, the power transmitted from the input port 611 to the direct port 612 and the power transmitted from the isolation port 613 to the direct port 612 have opposite phases and the same amplitudes. Since these two powers cancel each other, no power is output from the direct port 612 and no power is supplied to the resistor R1 (substitute for the control amplifier 3).

Next, the power supplied from the input port 611 or the isolation port 613 to the rat-race coupler 61 and output from the coupled port 614 will be described. As the power having the phase φ1 at the input port 611 which is equal to 0 degrees is transmitted to the coupled port 614, a phase delay of 270 degrees is added to the power, and thus the phase φ1 at the coupled port 614 is 270 degrees. As the power having the phase φ2 at the isolation port 613 which is equal to 180 degrees is transmitted to the coupled port 614, a phase delay of 90 degrees is added to the power, and thus the phase φ2 at the coupled port 614 is 270 degrees. Thus, the power transmitted from the input port 611 to the coupled port 614 and the power transmitted from the isolation port 613 to the coupled port 614 have the same phases and the same amplitudes. The power in which these two powers are constructive is output from the coupled port 614 and supplied to the resistor R2 (substitute for the load 902) as the output power Pout.

In this manner, by making the input power (phase φ1) to the input port 611 and the input power (phase φ2) to the isolation port 613 opposite in phase, it is possible to efficiently supply power to the load 902 while suppressing unnecessary power supply to the control amplifier 3.

### Second Condition of Phase Control

The term “second condition” means a phase condition for matching the operation timing of the load modulation between the first amplifier 1 and the second amplifier 2. More specifically, the second condition is a condition for appropriately setting a relationship between a phase of power output from each amplifier and a phase of the control signal Pctrl transmitted to each amplifier.

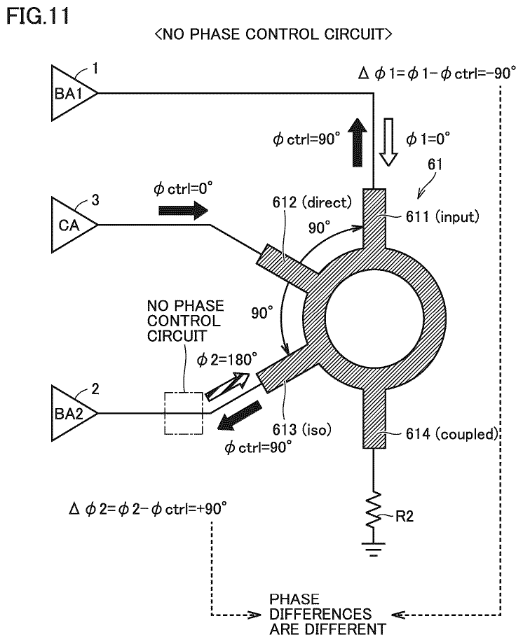

FIG. 11 is a diagram for describing a case where the phase control circuit 72 is not provided. As indicated by black arrows, a part of the control signal Pctrl output from the control amplifier 3 to the direct port 612 is transmitted to the first amplifier 1 via the input port 611, and the other part is transmitted to the second amplifier 2 via the isolation port 613.

The phase of the control signal Pctrl is denoted by φctrl. As the control signal Pctrl is transmitted from the direct port 612 to the input port 611, a phase delay of 90 degrees is added. Similarly, as the control signal Pctrl is transmitted from the direct port 612 to the isolation port 613, a phase delay of 90 degrees is added.

A phase difference of the input power from the first amplifier 1 to the input port 611 having the phase φ1 (indicated by the white arrow) with respect to the control signal Pctrl output from the input port 611 to the first amplifier 1 is denoted by Δφ1. That is, the phase difference Δφ1 satisfies Δφ1=φ1−φctrl. A phase difference of the input power from the second amplifier 2 to the isolation port 613 having the phase φ2 (indicated by an arrow with diagonal hatching) with respect to the control signal Pctrl output from the isolation port 613 to the second amplifier 2 is denoted by Δφ2. That is, the phase difference Δφ2 satisfies Δφ2 =φ2-φctrl.

The second condition is a condition that the phase difference Δφ1 relating to the first amplifier 1 and the phase difference Δφ2 relating to the second amplifier 2 are equal to each other. In this example, it is assumed that the phase φctrl of the control signal Pctrl at the direct port 612 is equal to 0 degrees.

As in FIG. 10, when the phase φ1 of the input power to the input port 611 is set to 0 degrees and the phase φ2 of the input power to the isolation port 613 is set to 180 degrees, the first condition is satisfied.

The phase φctrl of the control signal Pctrl in the first amplifier 1 is 90 degrees. When the phase control circuit 72 is not provided, the phase φctrl of the control signal in the second amplifier 2 is also 90 degrees. Then, the phase difference Δφ1 satisfies Δφ1=φ1−φctrl=0 degrees −90 degrees=−90 degrees, and the phase difference Δφ2 satisfies Δφ2=φ2−φctrl=180 degrees −90 degrees=90 degrees. That is, the phase difference Δφ1 in the first amplifier 1 and the phase difference Δφ2 in the second amplifier 2 are different from each other. Thus, the second condition is not satisfied.

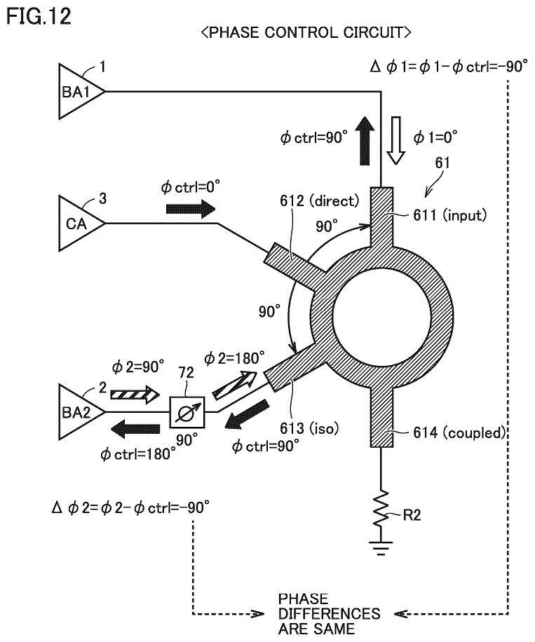

FIG. 12 is a diagram for describing a second condition regarding a phase relationship between power and a control signal. In FIG. 12, the phase control circuit 72 is provided between the output node of the second amplifier 2 and the isolation port 613. In the present example, the phase φ2 of the power output from the second amplifier 2 to the phase control circuit 72 is set to 90 degrees. The phase delay amount by the phase control circuit 72 is set to 90 degrees.

First, the first condition will be described. The phase φ2 of the input power from the second amplifier 2 to the isolation port 613 is 180 degrees because the phase delay of 90 degrees is added by the phase control circuit 72. The phase φ1 of the input power from the first amplifier 1 to the input port 611 is 0 degrees, as in the case where the phase control circuit 72 is not provided. That is, the input power to the input port 611 and the input power to the isolation port 613 have opposite phases. Thus, the first condition is satisfied.

Next, the second condition will be described. The phase φctrl of the control signal Pctrl output from the isolation port 613 is 90 degrees. Since a phase delay of 90 degrees is added to this signal component by the phase control circuit 72, the phase φctrl of the control signal Pctrl in the second amplifier 2 is 180 degrees. Then, the phase difference Δφ2 in the second amplifier 2 is calculated as Δφ2=φ2−φctrl =90 degrees −180 degrees=−90 degrees. The phase φctrl of the control signal Pctrl output from the input port 611 is also 90 degrees. As for this signal component, the phase difference Δφ1 in the first amplifier 1 is calculated as Δφ1=φ1−φctrl=0 degrees −90 degrees=−90 degrees, as in the case where the phase control circuit 72 is not provided. That is, the phase difference Δφ1 in the first amplifier 1 and the phase difference Δφ2 in the second amplifier 2 are equal to each other. Thus, the second condition is also satisfied.

By satisfying the second condition, the phase relationship (phase difference Δφ1) between the output power from the first amplifier 1 and the control signal Pctrl to the first amplifier 1 is aligned with the phase relationship (phase difference Δφ2) between the output power from the second amplifier 2 and the control signal Pctrl to the second amplifier 2, and thus the operation timing of the load modulation is matched. Thus, the first amplifier 1 and the second amplifier 2 can be appropriately operated in the load modulation operation by the control signal Pctrl.

As described above, in the present example, the divider 4A (the first Wilkinson divider 41 and the second Wilkinson divider 42) is used to set the phase φ2 of the power output from the second amplifier 2 to the phase control circuit 72 to 90 degrees with respect to the phase φ1 of the power output from the first amplifier 1 which is equal to 0 degrees, and to set the phase delay amount by the phase control circuit 72 to 90 degrees, so that the first condition and the second condition can be satisfied at the same time.

### Other Arrangement Examples

An arrangement of the phase control circuit 72 is not limited to the arrangement shown in each of FIGS. 9 and 12. The phase control circuit 72 may be disposed at other positions. The phase delay amount may be appropriately set by the phase control circuit 72 in accordance with the arrangement of the phase control circuit 72.

FIG. 13 is a diagram for describing a second example of an arrangement of the phase control circuit 72. In this example, the phase control circuit 72 is coupled between the output node of the first amplifier 1 and the input port 611. The phase φ2 of the power output from the second amplifier 2 is set to 90 degrees. The phase delay amount by the phase control circuit 72 is set to 270 degrees. Although detailed description will not be repeated, the first condition and the second condition can be satisfied at the same time even in such a setting.

FIG. 14 is a diagram for describing a third example of the arrangement of the phase control circuit 72. As shown in FIG. 14, two or more phase control circuits 72 may be provided. In this example, a first phase control circuit 72A is coupled between the output node of the first amplifier 1 and the input port 611, and a second phase control circuit 72B is coupled between the output node of the second amplifier 2 and the isolation port 613. In this case, for example, the phase φ2 of the power output from the second amplifier 2 to the second phase control circuit 72B may be set to 90 degrees, the phase delay amount by the first phase control circuit 72A may be set to 90 degrees, and the phase delay amount by the second phase control circuit 72B may be set to 180 degrees. This also makes it possible to satisfy the first condition and the second condition at the same time.

### Simulation

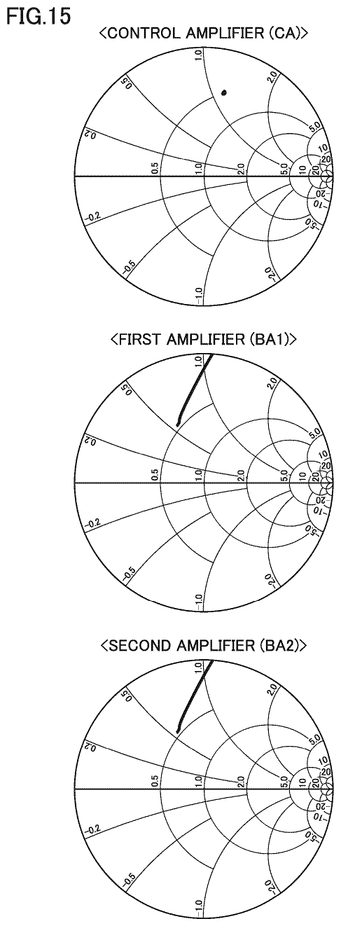

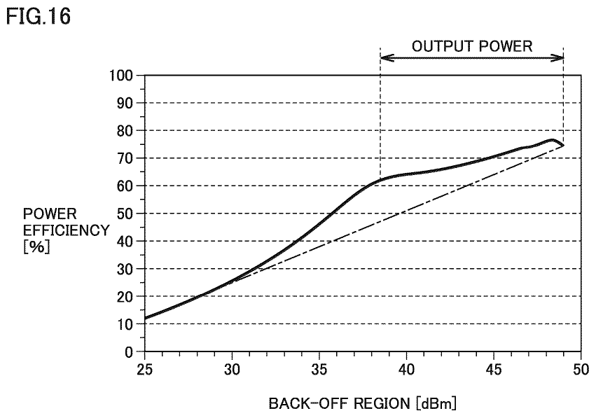

FIG. 15 illustrates Smith charts showing examples of simulation results regarding impedance matching of the power amplifier 101 according to the example 1 of the embodiment 1. FIG. 15 shows, from the top, changes in the impedances of the control amplifier 3, the first amplifier 1, and the second amplifier when load modulation is performed by the fundamental wave component of the control signal Pctrl. These are obtained by simulation in the circuit configuration shown in FIG. 9. The same applies to the simulation of FIG. 16 described later.

As shown in FIG. 15, it was confirmed that the control amplifier 3 was not load-modulated. In addition, it was also confirmed that the impedance of the first amplifier 1 and the impedance of the second amplifier 2 were equal to each other, in other words, the first amplifier 1 and the second amplifier 2 were impedance-matched by load modulation. This indicates that the power amplifier 101 normally performs the load modulation operation.

FIG. 16 is a diagram showing an example of a simulation result relating to power efficiency of the power amplifier 101 according to the example 1 of the embodiment 1. The horizontal axis represents the output power of the power amplifier 101, and the vertical axis represents the power efficiency of the power amplifier 101. For comparison, the dashed line indicates the output power dependency (tendency) of the power efficiency in a typical single power amplifier (single amplifier).

It can be seen from FIG. 16 that the power efficiency of the power amplifier 101 in the back-off region is improved by the load modulation operation of the power amplifier 101 in comparison with the single amplifier.

### Summary

As described above, in the embodiment 1, the first amplifier 1 and the second amplifier 2 form a balanced type amplifier together with the directional coupler having a phase difference of 180 degrees. When the directional coupler having a phase difference of 180 degrees is the rat-race coupler 61 shown in FIG. 5, the input port 611 coupled to the first amplifier 1 and the isolation port 613 coupled to the second amplifier 2 are not adjacent to each other. The direct port 612 is located between the input port 611 and the isolation port 613. Thus, by coupling the control amplifier 3 to the direct port 612, the control amplifier 3 is disposed between the first amplifier 1 and the second amplifier 2. The same applies to the case where the directional coupler having a phase difference of 180 degrees is the rat-race coupler 62 shown in FIG. 6.

By disposing the control amplifier 3 between the first amplifier 1 and the second amplifier 2, the distance between the first amplifier 1 and the second amplifier 2 is maintained, and the control amplifier 3 serves as the shield between the first amplifier 1 and the second amplifier 2. Thus, positive feedback between the first amplifier 1 and the second amplifier 2 becomes less likely to be applied. As a result, oscillation in the power amplifier 100 and the power amplifier 101can be suppressed.

### Embodiment 2

In the embodiment 1, the configuration in which the coupler 6 is the directional coupler (asymmetric directional coupler) having a phase difference of 180 degrees has been described. In the embodiment 2, a configuration in which the coupler 6 is a directional coupler (symmetrical directional coupler) having a phase difference of 90 degrees will be described.

### Example 1 of Embodiment 2

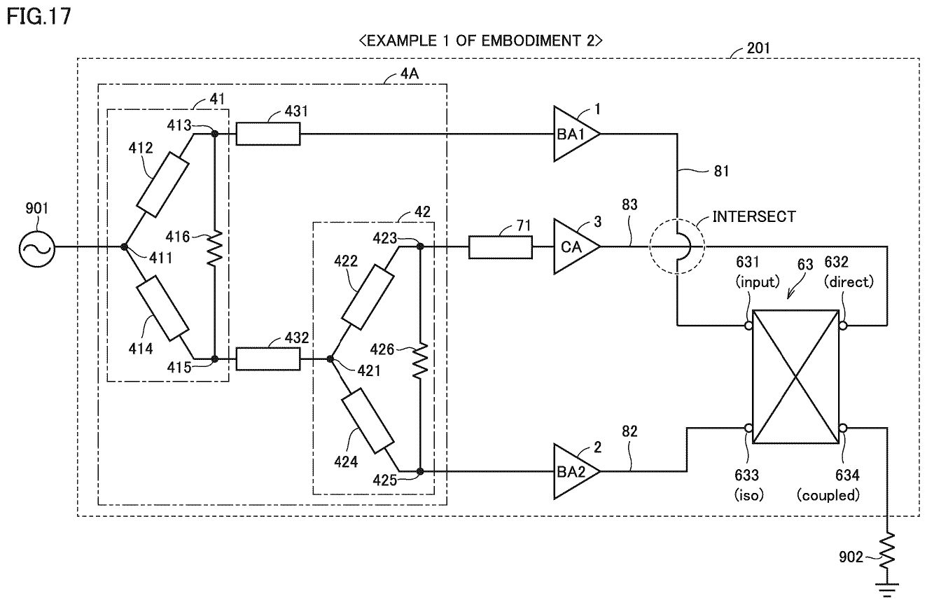

FIG. 17 is a circuit block diagram showing an example of a configuration of a power amplifier according to an example 1 of the embodiment 2. A power amplifier 201 is different from the power amplifier 101 according to the example 1 of the embodiment 1 (see FIG. 9) in that the power amplifier 201 includes a branch line coupler 63 instead of the rat-race coupler 61.

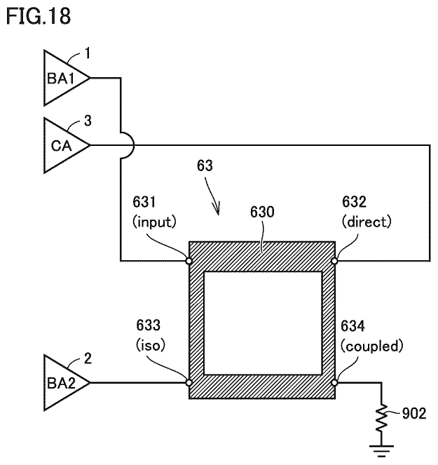

FIG. 18 is a diagram showing an example of a configuration of the branch line coupler 63. Referring to FIGS. 17 and 18, the branch line coupler 63 has a rectangular distribution line 630, an input port 631, a direct port 632, an isolation port 633, and a coupled port 634. These ports are arranged in the order of the input port 631, the isolation port 633, the coupled port 634, and the direct port 632 counterclockwise along an outer periphery of the branch line coupler 63 or the distribution line 630. The four ports may be arranged in the same order in a clockwise direction.

Note that the input port 631 corresponds to the “first port” according to the present disclosure. The isolation port 633 corresponds to the “second port” according to the present disclosure. The coupled port 634 corresponds to the “fourth port” according to the present disclosure. The direct port 632 corresponds to the “third port” according to the present disclosure.

The input port 631 is coupled to the output node of the first amplifier 1 by a transmission line 81. The direct port 632 is coupled to the output node of the control amplifier 3 by a transmission line 83. The isolation port 633 is coupled to the output node of the second amplifier 2 by a transmission line 82. The coupled port 634 is coupled to the load 902.

The transmission line 81, the transmission line 82, and the transmission line 83 are mounted at a multilayer substrate including a plurality of conductor layers. As such a mounting technique, for example, a technique of a multilayered monolithic microwave integrated circuit (MMIC) can be used. The multilayer substrate may contain a double-sided substrate.

The transmission line 81 and the transmission line 83 are mounted on different conductor layers among the plurality of conductor layers and three-dimensionally intersect each other. Thus, it is possible to dispose the control amplifier 3 between the first amplifier 1 and the second amplifier 2 while adopting the branch line coupler 63 in which the input port 631 and the isolation port 633 are disposed adjacent to each other. The transmission line 81, the transmission line 82, and the transmission line 83 correspond to the “first transmission line”, the “second transmission line”, and the “third transmission line” according to the present disclosure, respectively.

A general commercially available coupler may be adopted instead of the branch line coupler 63. Even when a commercially available coupler is adopted, the control amplifier 3 can be disposed between the first amplifier 1 and the second amplifier 2 by using a multilayer

### Example 2 of Embodiment 2

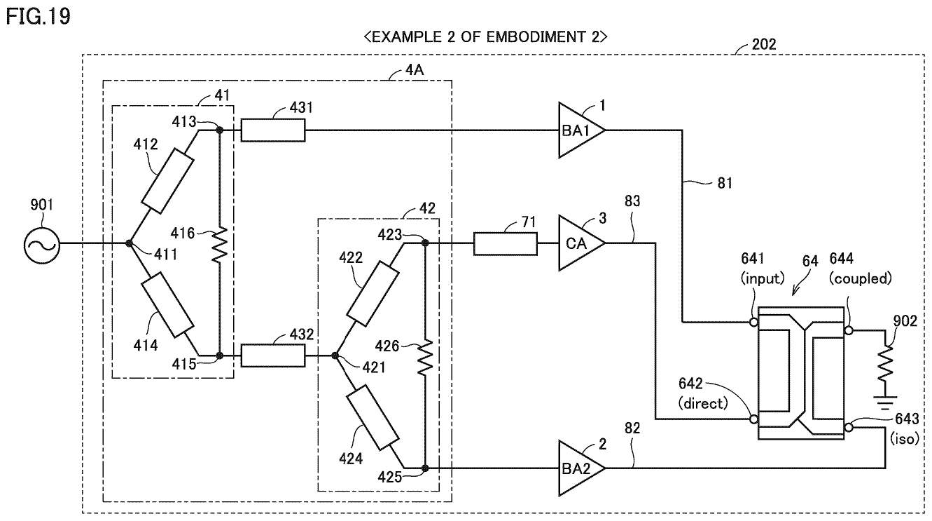

FIG. 19 is a circuit block diagram showing an example of a configuration of a power amplifier according to an example 2 of the embodiment 2. A power amplifier 202 is different from the power amplifier 201 according to the example 1 of the embodiment 2 (see FIG. 17) in that the power amplifier 202 includes a distributed coupling coupler 64 instead of the branch line coupler 63.

The distributed coupling coupler 64 includes an input port 641, a direct port 642, an isolation port 643, and a coupled port 644. These ports are arranged in the order of the input port 641, the coupled port 644, the isolation port 643, and the direct port 642 clockwise along an outer periphery of the distributed coupling coupler 64. That is, the order of arrangement of the four ports is different between the branch line coupler 63 and the distributed coupling coupler 64.

Note that the input port 641 corresponds to the “first port” according to present disclosure. The coupled port 644 corresponds to the “fourth port” according to the present disclosure. The isolation port 643 corresponds to the “second port” according to the present disclosure. The direct port 642 corresponds to the “third port” according to the present disclosure.

The input port 641 is coupled to the output node of the first amplifier 1 by the transmission line 81. The direct port 642 is coupled to the output node of the control amplifier 3 by the transmission line 83. The isolation port 643 is coupled to the output node of the second amplifier 2 by the transmission line 82. The coupled port 644 is coupled to the load 902.

In the example 2, unlike the example 1, the transmission line 81 and the transmission line 83 do not intersect each other. This is due to the adoption of the distributed coupling coupler 64.

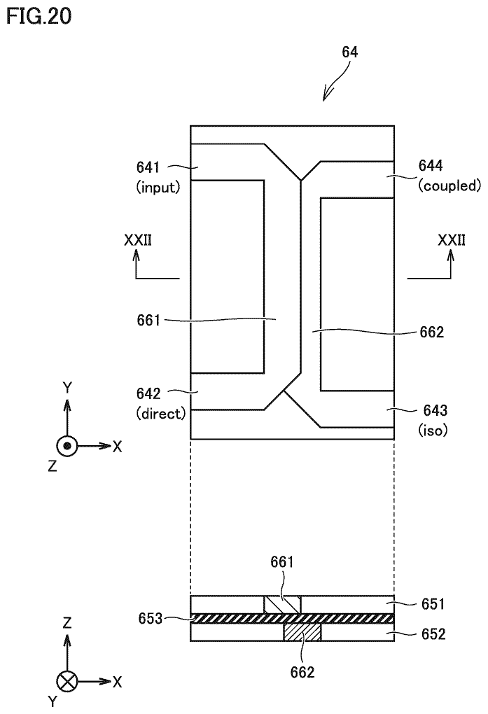

FIG. 20 is a diagram for describing a configuration of the distributed coupling coupler 64. FIG. 20 shows a perspective view (see an upper diagram) of the distributed coupling coupler 64 viewed in a plan view and a cross-sectional view (see the lower diagram) of the distributed coupling coupler 64 taken along the line XXII-XXII.

The distributed coupling coupler 64 is substantially rectangular flat shape extending in the XY plane direction when the XY plane direction is viewed in a plan view along the Z direction in the drawing. The Z direction is a thickness direction of the distributed coupling coupler 64. The distributed coupling coupler 64 has a multilayer structure in which a first conductive layer 651, an insulating layer 653, and a second conductive layer 652 are stacked in this order in the thickness direction.

The input port 641 and the direct port 642 are arranged on the same side of the rectangle in the first conductive layer 651. The isolation port 643 and the coupled port 644 are arranged on the same side of the rectangle (the side opposite to the input port 641 and the direct port 642) in the second conductive layer 652. The input port 641 and the direct port 642 are coupled by a wiring 661 in the first conductive layer 651, and the isolation port 643 and the coupled port 644 are coupled by a wiring 662 in the second conductive layer 652.

The wiring 661 and the wiring 662 are arranged close to each other so as to be electromagnetically coupled to each other through the insulating layer 653. In this example, the wiring 661 and the wiring 662 are arranged so as to at least partially overlap each other when the distributed coupling coupler 64 is viewed in a plan view. As described above, since the wiring 661 and the wiring 662 three-dimensionally intersect each other inside the distributed coupling coupler 64, the transmission lines do not have to intersect each other outside the distributed coupling coupler 64. Note that the wiring 661 and the wiring 662 correspond to the “first wiring” and the “second wiring”according to the present disclosure, respectively.

### Summary

As described above, in the embodiment 2, the first amplifier 1 and the second amplifier 2 form the balanced type amplifier together with the directional coupler having a phase difference of 90 degrees. When the directional coupler having a phase difference of 90 degrees is the branch line coupler 63 (see FIGS. 17 and 18), the input port 631 and the isolation port 633 are adjacent to each other in the branch line coupler 63. However, the control amplifier 3 can be disposed between the first amplifier 1 and the second amplifier 2 by three-dimensional intersection of the transmission line 81 and the transmission line 83 using the multilayer substrate outside the branch line coupler 63.

By disposing the control amplifier 3 between the first amplifier 1 and the second amplifier 2, the distance between the first amplifier 1 and the second amplifier 2 is maintained, and the control amplifier 3 serves as the shield between the first amplifier 1 and the second amplifier 2. Thus, positive feedback between the first amplifier 1 and the second amplifier 2 becomes less likely to occur. As a result, oscillation in the power amplifier 201 can be suppressed.

In the case where the directional coupler having a phase difference of 90 degrees is the distributed coupling coupler 64 (see FIGS. 19 and 20), the input port 641 and the isolation port 643 are not adjacent to each other, and the direct port 642 is located between the input port 641 and the isolation port 643. Thus, by coupling the control amplifier 3 to the direct port 642, the control amplifier 3 is disposed between the first amplifier 1 and the second amplifier 2.

In the distributed coupling coupler 64, the wiring 661 and the wiring 662 are coupled to each other while being disposed on different conductive layers inside the distributed coupling coupler 64, and thus it is not necessary to three-dimensionally crossing the transmission lines outside the distributed coupling coupler 64.

Even when the distributed coupling coupler 64 is used, oscillation in the power amplifier 202 can be suppressed as in the case where the branch line coupler 63 is used.

The configurations described in the embodiment 1, the embodiment 2, and the examples thereof may be combined as appropriate.

The embodiments disclosed herein are to be considered in all respects as illustrative and not restrictive. The scope of the present invention is defined not by the above-described embodiments but by the appended claims, and is intended to include any modifications within the meaning and scope equivalent to the appended claims.

What is claimed is:

1. A power amplifier comprising:
a balanced type amplifier including a first amplifier and a second amplifier and configured to amplify an input power; and
a control amplifier configured to form a load modulated balanced amplifier together with the balanced type amplifier and output a control signal including a fundamental wave component or a harmonic component of the input power to each of the first amplifier and the second amplifier,
wherein the control amplifier is disposed between the first amplifier and the second amplifier.

2. The power amplifier according to claim 1, wherein
the balanced type amplifier includes a directional coupler having a plurality of ports and a phase difference of 180 degrees,
the plurality of ports includes:
a first port configured to receive a power amplified by the first amplifier;
a second port configured to receive a power amplified by the second amplifier;
a third port configured to receive the control signal; and
a fourth port coupled to a load, and
the third port is disposed between the first port and the second port along an outer periphery of the directional coupler having a phase difference of 180 degrees.

3. The power amplifier according to claim 2, wherein
the directional coupler having a phase difference of 180 degrees is a rat-race coupler having a distribution line,
the first port, the third port, the second port, and the fourth port are arranged in this order along the distribution line, and
the power amplifier further includes one or more phase control circuits configured to control a phase of the power amplified by the second amplifier with respect to a phase of the power amplified by the first amplifier.

4. The power amplifier according to claim 3, wherein
the rat-race coupler is a ring loose coupled rat-race coupler in which the distribution line has a ring shape.

5. The power amplifier according to claim 3, wherein
the rat-race coupler is a coupled-line rat-race coupler having two coupled lines between the first port and the fourth port, the two coupled lines being arranged to be coupled to each other.

6. The power amplifier according to claim 1, wherein
the balanced type amplifier includes a directional coupler having a plurality of ports and a phase difference of 90 degrees, and
the plurality of ports includes:
a first port configured to receive a power amplified by the first amplifier;
a second port configured to receive a power amplified by the second amplifier;
a third port configured to receive the control signal; and
a fourth port coupled to a load.

7. The power amplifier according to claim 6, wherein
the directional coupler having a phase difference of 90 degrees is a branch line coupler having a distribution line,
the first port, the second port, the fourth port, and the third port are arranged in this order along the distribution line,
the first port is coupled to the first amplifier by a first transmission line,
the second port is coupled to the second amplifier by a second transmission line,
the third port is coupled to the control amplifier by a third transmission line,
the first transmission line, the second transmission line, and the third transmission line are mounted at a multilayer substrate including a plurality of conductor layers, and
the first transmission line and the third transmission line are mounted on different conductor layers among the plurality of conductor layers and three-dimensionally intersect each other such that the control amplifier is disposed between the first amplifier and the second amplifier.

8. The power amplifier according to claim 6, wherein
the directional coupler having a phase difference of 90 degrees is a distributed coupling coupler,
the first port, the fourth port, the second port, and the third port are arranged in this order along an outer periphery of the distributed coupling coupler,
the distributed coupling coupler has a multilayer structure including a first conductive layer and a second conductive layer,
the first port and the third port are coupled to each other by a first wiring disposed in the first conductive layer,
the second port and the fourth port are coupled to each other by a second wiring disposed in the second conductive layer, and
the first wiring and the second wiring are arranged so as to at least partially overlap each other when the distributed coupling coupler is viewed in a plan view.

9. The power amplifier according to claim 1, further comprising:
a divider configured to divide the input power for the first amplifier, the second amplifier, and the control amplifier.

10. The power amplifier according to claim 9, wherein
the divider includes a first Wilkinson divider and a second Wilkinson divider,
the first Wilkinson divider is configured to divide the input power for the first amplifier and the second Wilkinson divider, and
the second Wilkinson divider is configured to further divide the input power divided by the first Wilkinson divider, for the second amplifier and the control amplifier.
